(19) United States
(12) Patent Application Publication
(10) Pub. No.: US 2026/0060056 A1
(43) Pub. Date: Feb. 26, 2026

(54) INTERCONNECT STRUCTURE INCLUDING VIAS WITH DIFFERENT PROFILES AND METHOD FOR MANUFACTURING THE SAME

(71) Applicant: TAIWAN SEMICONDUCTOR MANUFACTURING COMPANY, LTD., Hsinchu (TW)

(72) Inventors: Jen-Pan WANG, Hsinchu (TW); Hsiao-Chiu HSU, Hsinchu (TW)

(73) Assignee: TAIWAN SEMICONDUCTOR MANUFACTURING COMPANY, LTD., Hsinchu (TW)

(21) Appl. No.: 18/810,711

(22) Filed: Aug. 21, 2024

(51) Int. Cl. H01L 21/768; H01L 23/522; H01L 23/528; H01L 23/532

(52) U.S. Cl. CPC H01L 21/76831; H01L 21/76816; H01L 21/76832; H01L 21/76877; H01L 23/5226; H01L 23/528; H01L 23/53295

(57) ABSTRACT

A method for manufacturing an interconnect structure includes: forming first and second etch stop layers respectively on first and second lower conductive portions, the first and second etch stop layers having different configurations; forming a dielectric layer to cover the first and second etch stop layers; performing a first etching process to form a first hole and a second hole in the dielectric layer to expose at least one of the first and second etch stop layers; performing a second etching process to form a first opening extending downwardly from the first hole and through the first etch stop layer, and to form a second opening extending downwardly from the second hole and through the second etch stop layer; and forming a first upper conductive portion in the first hole and the first opening, and forming a second upper conductive portion in the second hole and the second opening.

### BACKGROUND

With rapid development of semiconductor technology, an increasing number of devices with different functions are being integrated in an integrated circuit, increasing the complexity of integrated circuit design. Since the driving voltages of the devices may be different from each other, the resistance of the wires (metal lines or metal vias) respectively connected thereto may be designed to be different. Therefore, a method for manufacturing a back-end interconnecting structure with flexibility in routing design is being continuously developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnecting structure in accordance with some embodiments.

FIGS. 2 to 19 are schematic views illustrating intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

In common practice, a back-end interconnecting structure includes multiple interconnect layers. Vias located in an upper one of the interconnect layers extend through the same etch stop layer so as to be connected to metal lines in a lower one of the interconnect layers. In such case, since a single type of the etch stop layer is located between the upper and lower ones of the interconnect layers, the resistance of one of the vias located in the upper one of the interconnect layer cannot be changed individually. Therefore, the present disclosure is directed to a method for manufacturing an interconnect layer which includes multiple vias in the same interconnect layer such that the multiple vias have adjustable resistances which can be independently changed.

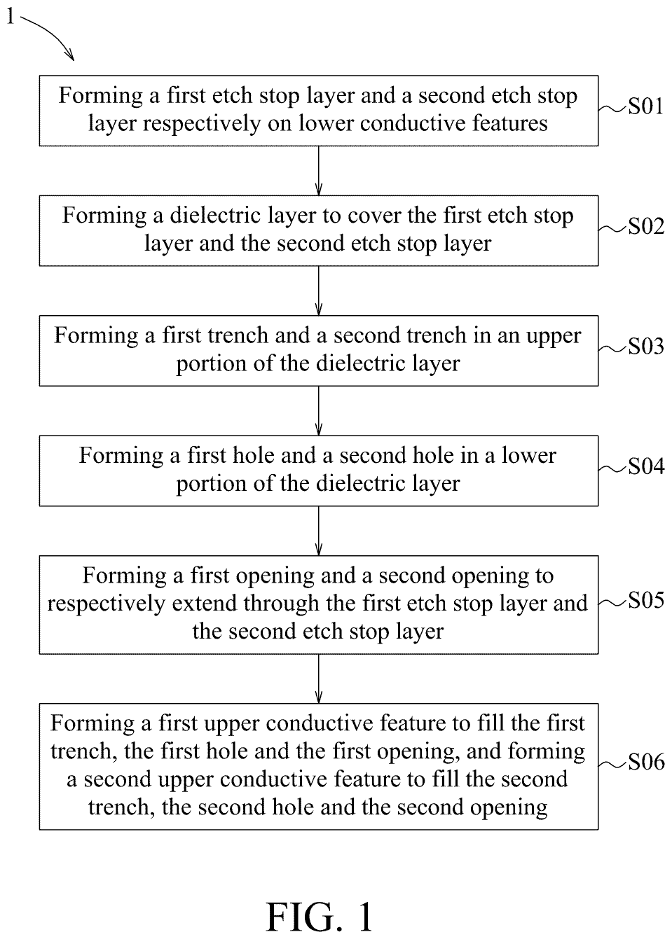

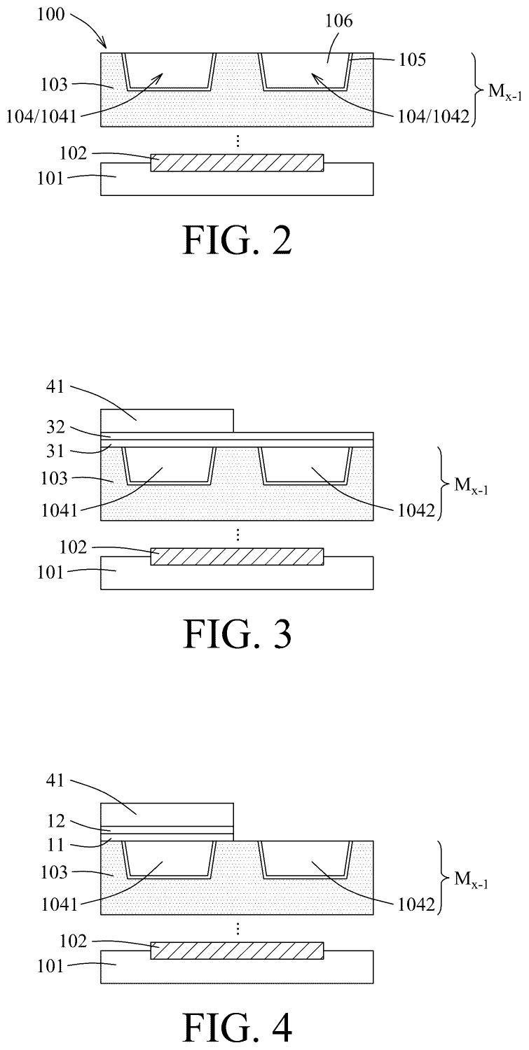

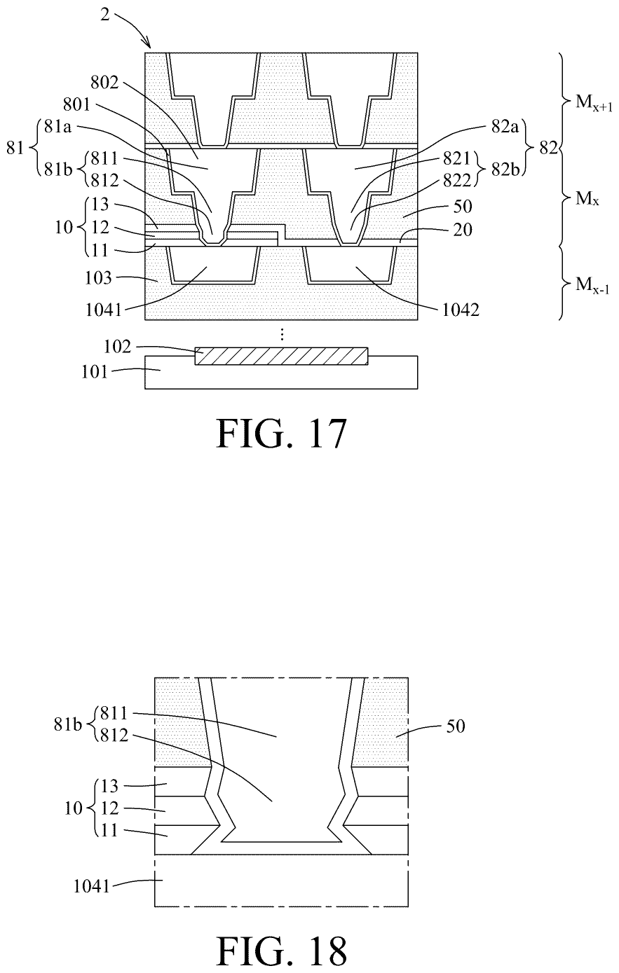

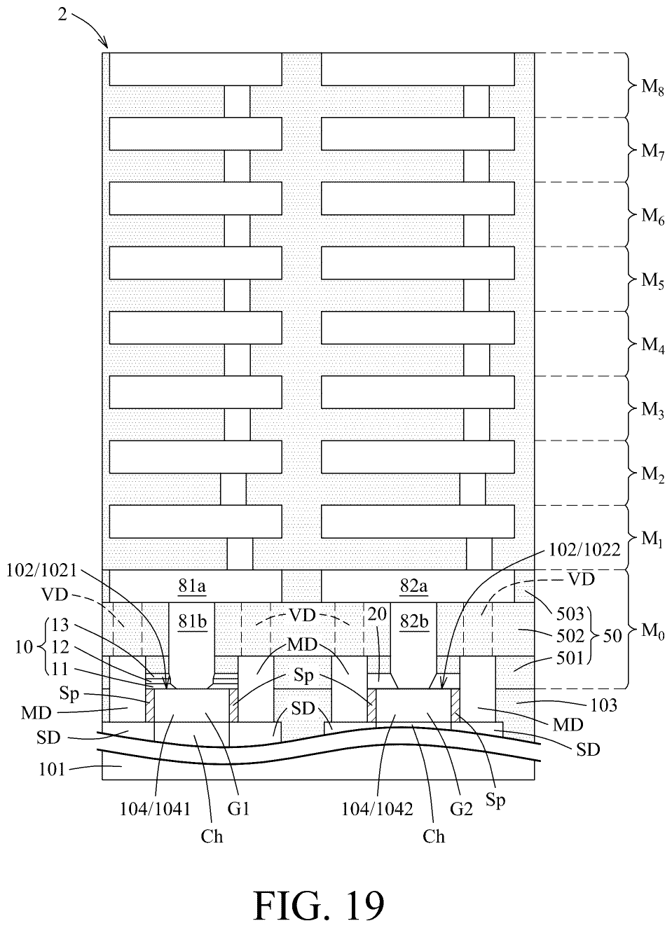

FIG. 1 is a flow diagram illustrating a method 1 for manufacturing an interconnecting structure (e.g., an interconnecting layer Mₓ shown in FIG. 17 or an interconnecting layer M₀ shown in FIG. 19) in a semiconductor structure 2 in accordance with some embodiments. The method 1 may include steps S01 to S06. FIGS. 2 to 19 are schematic views illustrating intermediate stages of the method 1 in accordance with some embodiments.

FIG. 2 is a schematic sectional view illustrating a base structure 100 in accordance with some embodiments. In some embodiments, the base structure 100 is a device wafer including active devices (for example, transistors, diodes, or the like), passive devices (for example, capacitors, inductors, resistors, or the like), decoders, amplifiers, or combinations thereof.

In some embodiments, the base structure 100 includes a substrate 101 and a plurality of semiconductor devices 102 (one of which is exemplarily shown in FIG. 2) formed on the substrate 101. In some embodiments, the substrate 101 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 101 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 101 may be configured as a semiconductor-on-insulator substrate. Other suitable materials and configurations for the substrate 101 are within the contemplated scope of the present disclosure. In some embodiments, the substrate 101 may be formed with trench isolations (not shown) to separate the semiconductor device 102 from an adjacent ones of the semiconductor devices. In some embodiments, the trench isolations may each be a shallow trench isolation (STI), a deep trench isolation (DTI), or other suitable structures. In some embodiments, the trench isolations may include silicon oxide, silicon nitride, silicon oxynitride, other low-k dielectric materials, or combinations thereof. In some embodiments, the semiconductor device 102 may include a transistor, but is not limited thereto.

In some embodiments, the base structure 100 further includes an interconnect layer Mₓ₋₁, where x is an integer not less than 1. The interconnect layer Mₓ₋₁ includes a dielectric layer 103 (which may be referred to as a lower dielectric layer) and conductive features 104 (which may be also referred to as lower conductive features) formed in the dielectric layer 103. As shown in FIG. 2, the conductive features 104 include a conductive feature 1041 and a conductive feature 1042 which are spaced apart from each other by the dielectric layer 103. The interconnect layer Mₓ₋₁ is formed on the semiconductor device 102 so as to permit the semiconductor device 102 to be electrically connected to an external circuit through the conductive features 104.

In some embodiments, the dielectric layer 103 includes a low-dielectric constant (low-k) material. In some embodiments, the dielectric layer 103 may include silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low dielectric constant materials, or combinations thereof. Other possible materials suitable for the dielectric layer 103 are within the contemplated scope of the present disclosure.

In some embodiments, the conductive features 104 are metal lines. The conductive features 104 may each includes a diffusion barrier layer 105 and a conductive portion 106. The diffusion barrier layer 105 is disposed to separate the conductive portion 106 from the dielectric layer 103 so as to prevent the metal elements in the conductive portion 106 from diffusing into the dielectric layer 103. In some embodiments, the conductive portion 106 includes Co, Cu, Ni, Ru, W, Mo, Ti, Zr, Ta, Zn, or alloys thereof. In some embodiments, the diffusion barrier layer 105 includes titanium, titanium nitride, tantalum, tantalum nitride, or combinations thereof. Other materials suitable for the diffusion barrier layer 105 and the conductive portion 106 are also within the contemplated scope of the present disclosure. In some embodiments, the conductive features 104 may be formed as a single damascene structure or a dual damascene structure. In some other embodiments shown in FIG. 19 (will be described later), the conductive features 104 may each be a gate electrode connected to the semiconductor device 102.

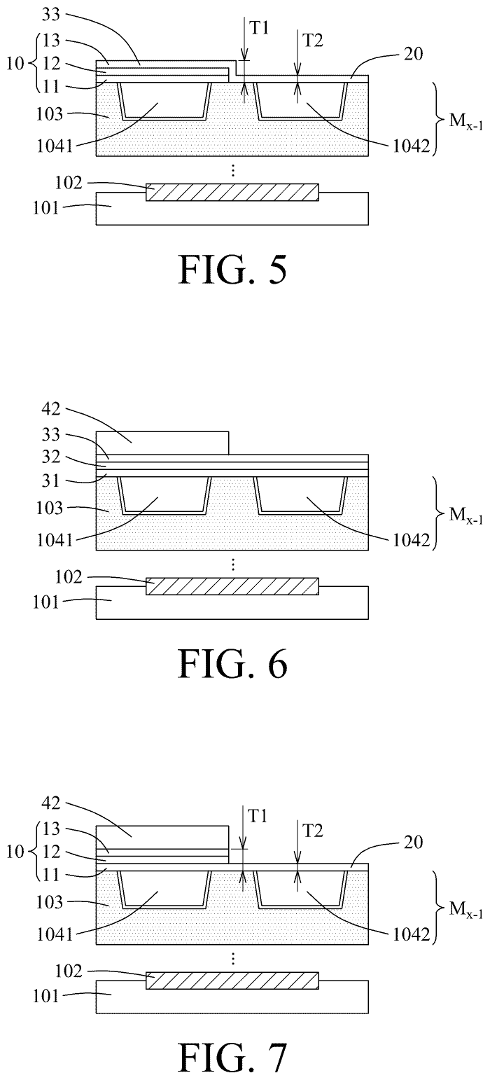

Referring to FIG. 1 and the examples illustrated in FIGS. 5 and 7, the method 1 begins at step S01, where a first etch stop layer 10 and a second etch stop layer 20 are respectively formed on the conductive feature 1041 and the conductive feature 1042. FIGS. 5 and 7 are each a schematic sectional view similar to that of FIG. 2, but illustrating two possible structures after step S01 in accordance with some embodiments. FIGS. 3 and 4 respectively illustrate two possible intermediate states in step S01 in accordance with some embodiments for forming the etch stop layers 10, 20 shown in FIG. 5, whereas FIG. 6 illustrates a possible intermediate state in step S01 in accordance with some other embodiments for forming the etch stop layers 10, 20 shown in FIG. 7.

The first etch stop layer 10 has a configuration that is different from a configuration of the second etch stop layer 20.

In some embodiments, as shown in FIGS. 5 and 7, the first etch stop layer 10 is configured as a multi-layered structure, and the second etch stop layer 20 is configured as a single layer structure. For example, the first etch stop layer 10 includes a first sub-layer 11, a second sub-layer 12 and a third sub-layer 13 which are sequentially formed on the conductive feature 1041 in such order. It is noted that the number of the sub-layers of the first etch stop layer 10 is not limited to three as shown in FIG. 5 or 7. In some other embodiments not shown herein, the number of the sub-layers of the fist etch stop layer 10 may be two, or greater than three. In some embodiments, a total thickness (T1) of the first etch stop layer 10 is greater than a total thickness (T2) of the second etch stop layer 20.

The first sub-layer 11 is made of a first dielectric material, the second sub-layer 12 is made of a second dielectric material, and the third dielectric material is made of a third dielectric material. In some embodiments, the first, second and third dielectric materials are different from each other so as to permit the first, second and third dielectric materials to have different etch rates in the following etching process (e.g., in step S05) using the same etchant. The first dielectric material includes or is made of silicon oxide, silicon carbide, silicon nitride, silicon oxynitride, silicon carbon nitride, silicon oxycarbon nitride, aluminum oxide, aluminum nitride, or aluminum oxynitride. The second dielectric material includes or is made of silicon oxide, silicon carbide, silicon nitride, silicon oxynitride, silicon carbon nitride, silicon oxycarbon nitride, aluminum oxide, aluminum nitride, or aluminum oxynitride. The third dielectric material includes or is made of silicon oxide, silicon carbide, silicon nitride, silicon oxynitride, silicon carbon nitride, silicon oxycarbon nitride, aluminum oxide, aluminum nitride, or aluminum oxynitride. It is noted that two of the first, second and third dielectric materials may have the same atom species. For example, but not limited to, the first and second dielectric materials may each have silicon, carbon and nitrogen elements, and concentrations of the silicon, carbon and nitrogen elements in the first dielectric material are respectively different from concentrations of the silicon, carbon and nitrogen elements in the second dielectric material, so that the etch rate of the first dielectric material can be significantly different from the etch rate of the second dielectric material. In some embodiments, when the dielectric constant (k-value) of the first, second or third dielectric material is larger, the etch rate of the first, second or third dielectric material may be lower. In some embodiments, the first sub-layer 11 has a thickness ranging from about 10 Å to about 100 Å. In some embodiments, the second sub-layer 12 has a thickness ranging from about 10 Å to about 100 Å. In some embodiments, the third sub-layer 13 has a thickness ranging from about 10 Å to about 100 Å. In some embodiments, the thicknesses of the first, second and third sub-layers 11, 12, 13 may be substantially equal to each other. In some alternative embodiments, the thicknesses of the first, second and third sub-layers 11, 12, 13 may be different from each other.

The second etch stop layer 20 is made of one of the first dielectric material, the second dielectric material and the third dielectric material. In certain embodiments, as shown in FIG. 5, the second etch stop layer 20 is made of the third dielectric material. In certain embodiments, as shown in FIG. 7, the second etch stop layer 20 is made of the first dielectric material.

In some embodiments, formation of the first and second etch stop layers 10, 20 shown in FIG. 5 may include multiple sub-steps as shown in FIGS. 3 to 5.

Firstly, as shown in FIG. 3, a first dielectric film 31 made of the first dielectric material and a second dielectric film 32 made of the second dielectric material are sequentially formed on the interconnect layer Mₓ₋₁ by atomic layer deposition (ALD), physical vapor deposition (PVD), chemical vapor deposition process (CVD), or other suitable deposition techniques. Then, a patterned photoresist layer 41 is partially formed on the dielectric films 32 by, for example, but not limited to, a spin coating, followed by an exposure process and a development process so as to expose a portion of the dielectric films 32 located above the conductive feature 1042.

Afterwards, as shown in FIGS. 3 and 4, the dielectric films 31, 32 are patterned to expose the conductive feature 1042. To be specific, the exposed portion of the dielectric film 32 and a portion of the dielectric film 31 located beneath the exposed portion of the dielectric film 32 are sequentially removed by an etching process, thus obtaining the first sub-layer 11 and the second sub-layer 12 of the first etch stop layer 10 (see FIG. 5).

Next, as shown in FIGS. 4 and 5, the photoresist layer 41 is removed by, for example, but not limited to, an ashing process and/or a photoresist stripping process, and then a third dielectric film 33 made of the third dielectric material is formed to cover the second sub-layer 12 and the conductive feature 1042 by ALD, CVD, PVD, or other suitable deposition techniques. A first portion of the third dielectric film 33, which is disposed on the second sub-layer 12, serves as the third sub-layer 13 of the first etch stop layer 10, and a second portion of the third dielectric film 33, which is disposed on the conductive feature 1042, serves as the second etch stop layer 20

FIG. 7 is a schematic sectional view similar to that of FIG. 5, but illustrating a variant of the configuration of the first and second etch stop layers 10, 20 in accordance with some other embodiments. The first and second etch stop layers 10, 20 shown in FIG. 7 have a configuration similar to that of the first and second etch stop layers 10, 20 shown in FIG. 5, but the second etch stop layer 20 is made of a material the same as that of the first sub-layer 11 of the first etch stop layer 10. That is, the second etch stop layer 20 is made of the first dielectric material. Formation of the first and second etch stop layers 10, 20 shown in FIG. 7 may include multiple sub-steps as shown in FIGS. 6 and 7.

Firstly, as shown in FIG. 6, the first dielectric film 31, the second dielectric film 32 and the third dielectric film 33 are sequentially formed on the interconnect layer Mₓ₋₁ by ALD, CVD, PVD, or other suitable deposition techniques. Then, a patterned photoresist layer 42 is partially formed on the third dielectric film 33 by, for example, but not limited to, a spin coating, followed by an exposure process and a development process so as to expose a portion of the third dielectric film 33 located above the conductive feature 1042.

Afterwards, as shown in FIGS. 6 and 7, the dielectric films 32, 33 are patterned to expose a first portion of the first dielectric film 31 located above the conductive feature 1042. To be specific, the exposed portion of the third dielectric film 33 which is exposed from the patterned photoresist layer 42, and a portion of the second dielectric film 32 which is disposed beneath the exposed portion of the third dielectric film 33 are removed by an etching process. Accordingly, the patterned dielectric films 33, 32 and a second portion of the first dielectric film 31 located beneath the patterned dielectric films 32, 33 respectively serve as the sub-layers 13, 12, 11 of the first etch stop layer 10. The first portion of the first dielectric film 31 serves as the second etch stop layer 20.

After the patterning of the dielectric films 32, 33, the photoresist layer 42 is removed by, for example, but not limited to, an ashing process and/or a photoresist stripping process.

In some alternative embodiments not shown herein, the first and second etch stop layers 10, 20 may be each configured as a single-layer structure, but the first and second etch stop layers 10, 20 are made of different materials.

For purposes of simplicity and clarity, in the following steps, the structures subsequent to FIG. 5 will be illustrated, while the structures subsequent to FIG. 7 will not be illustrated.

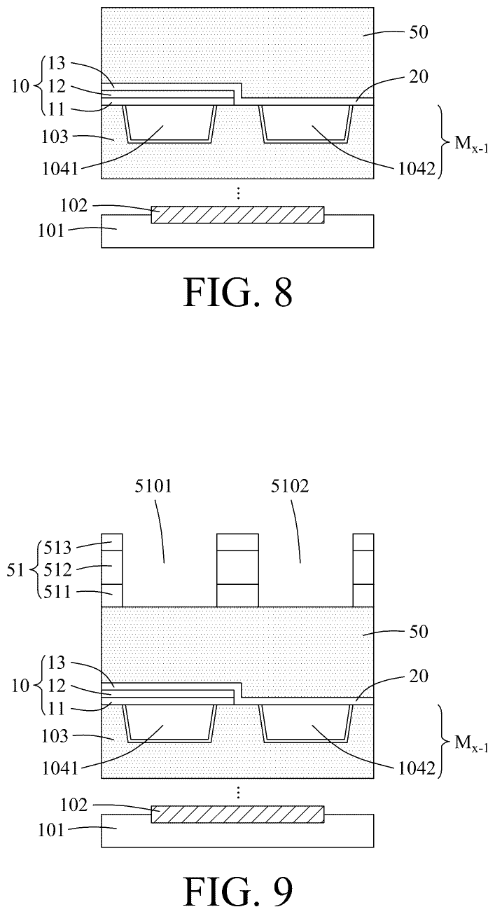

Referring to FIG. 1 and the example illustrated in FIG. 8, the method 1 proceeds to step S02, where a dielectric layer 50 (which may be referred to as an upper dielectric layer) is formed to cover the first and second etch stop layers 10, 20. FIG. 8 is a schematic sectional view similar to that of FIG. 5, but illustrating the structure after step S02 in accordance with some embodiments.

Possible low-k dielectric materials suitable for the dielectric layer 50 are similar to those for the dielectric layer 103 as described above with reference to FIG. 2, and thus the details thereof are omitted for the sake of brevity. The dielectric materials of the dielectric layer 103, 50 may be the same as or different from each other. In some embodiments, the dielectric layer 50 may be formed by ALD, CVD, PVD, or other suitable deposition techniques.

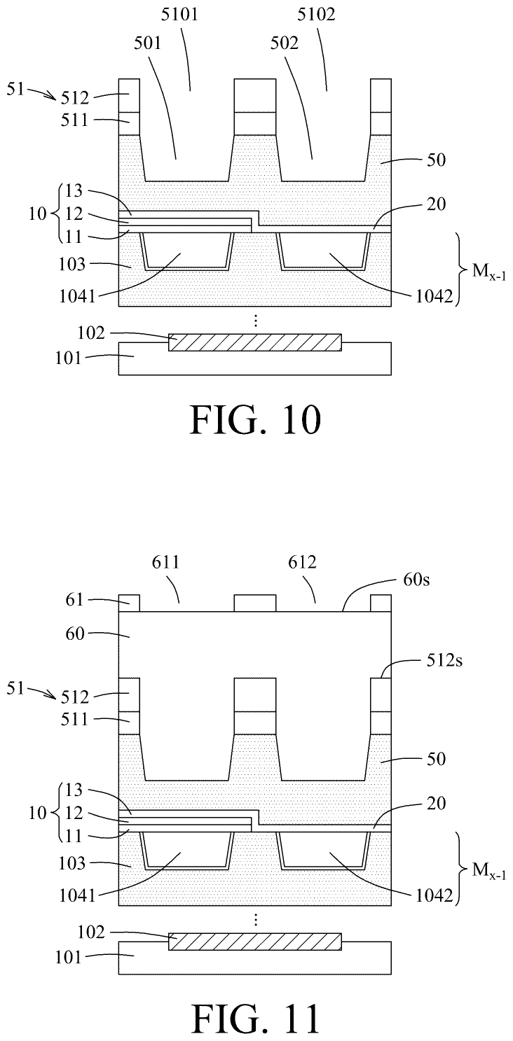

Referring to FIG. 1 and the example illustrated in FIG. 10, the method 1 proceeds to step S03, where a first trenches 501 and a second trench 502 are formed in an upper portion of the dielectric layer 50. FIG. 10 is a schematic sectional view similar to that of FIG. 8, but illustrating the structure after step S03 in accordance with some embodiments. In some embodiment, step S03 may include multiple sub-steps as shown in FIGS. 9 and 10.

Firstly, as shown in FIG. 9, a patterned mask layer 51 is formed on the dielectric layer 50. The patterned mask layer 51 is formed with a first opening 5101 and a second opening 5102 to expose portions of the dielectric layer 50. In some embodiments, the patterned mask layer 51 is formed by ALD, CVD, PVD, or other suitable deposition techniques, followed by a patterning process (for example, but not limited to, a double patterning process). In some embodiments, the patterned mask layer 51 may be configured as a multi-layered structure which includes sub-layers 511, 512, 513 stacked on each other. In some embodiments, the sub-layer 511 may include silicon oxide or other suitable materials, and may serve as a lower anti-reflective coating layer. In some embodiments, the sub-layer 512 may include a nitride-based material, such as silicon nitride, silicon oxynitride, metal nitride (e.g., aluminum nitride, tungsten nitride), or other suitable materials. In some embodiments, the sub-layer 513 may include silicon oxide or other suitable materials, and may serve as an upper anti-reflective coating layer.

Afterwards, as shown in FIGS. 9 and 10, a trench etching process is performed to etch an upper portion of the dielectric layer 50 through the openings 5101, 5102 of the patterned mask layer 51 (serving as a hard mask), thereby forming the trenches 501, 502. In some embodiments, the sub-layer 513 (see FIG. 9) may be consumed and removed during the trench etching process, leaving the sub-layers 511, 512 on the dielectric layer 50.

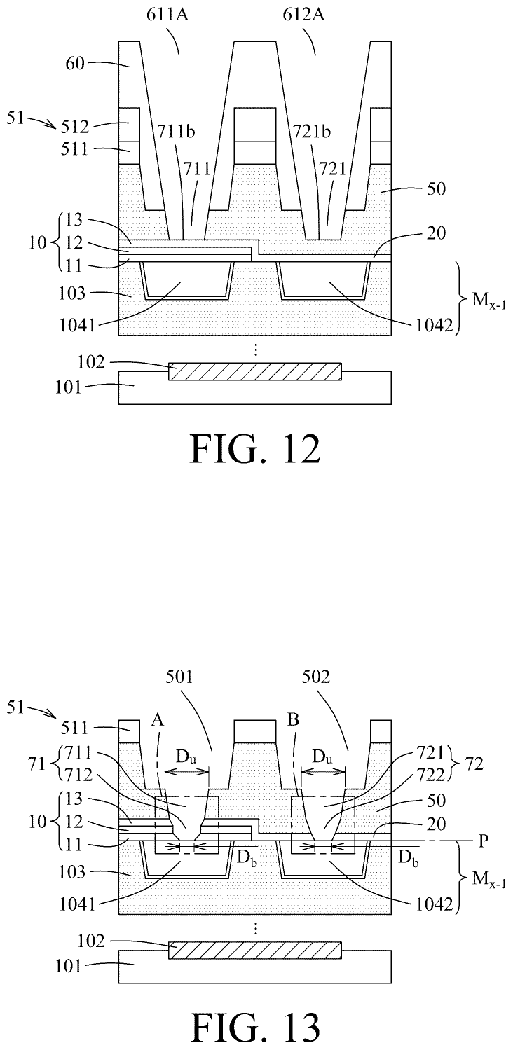

Referring to FIG. 1 and the example illustrated in FIG. 12, the method 1 proceeds to step S04, where a first hole 711 and a second hole 721 are formed in a lower portion of the dielectric layer 50. The holes 71, 72 are located immediately beneath the trenches 501, 502 (see FIG. 10 or 13), respectively. FIG. 12 is a schematic sectional view similar to that of FIG. 10, but illustrating the structure after step S04 in accordance with some embodiments. In some embodiment, step S04 may include multiple sub-steps as shown in FIGS. 11 and 12.

Firstly, as shown in FIG. 11, a filling layer 60 is formed to fill the trenches 501, 502 (see FIG. 10). In some embodiments, the filling layer 60 has a planar upper surface 60s which is at a level higher than that of an upper surface 512s of the sub-layer 512. In some embodiments, the filling layer 60 may be made of photoresist, and may be formed by a spin-on coating process, or other suitable deposition techniques. In some embodiments, the filling layer 60 may be made of amorphous carbon or ashless carbon, and may be formed by CVD, or other suitable deposition techniques.

Afterwards, as shown in FIG. 11, a patterned mask layer 61 is formed on the filling layer 60. The patterned mask layer 61 is formed with a first opening 611 and a second opening 612 to expose portions of the filling layer 60. The openings 611, 612 are spaced apart from each other. In some embodiments, the patterned mask layer 61 is formed by ALD, CVD, PVD, or other suitable deposition techniques, followed by a patterning process (for example, but not limited to, a double patterning process). In some embodiments, the patterned mask layer 61 includes a dielectric material such as silicon nitride, silicon oxide, silicon-oxynitride, or other suitable materials.

Next, as shown in FIGS. 11 and 12, a first via etching process is performed to etch the filling layer 60 and the lower portion of the dielectric layer 50 through the openings 611, 612 of the patterned mask layer 61 (serving as a hard mask). After the first via etching process, recesses 611A, 612A are formed to penetrate the filling layer 60, and the holes 711, 721 which respectively extend downwardly from the recesses 611A, 612A, are formed in the lower portion of the dielectric layer 50. At least one of the holes 711, 721 may penetrate the lower portion of the dielectric layer 50 to expose a corresponding one of the etch stop layers 10, 20. In some embodiments, as shown in FIG. 12, the first etch stop layer 10 is exposed from the first hole 711, whereas the second etch stop layer 20 is covered by the dielectric layer 50. In some other embodiments not shown herein, in the case that the etch stop layers 10, 20 have the same thickness, the etch stop layers 10, 20 may be respectively exposed from the holes 711, 721. In some embodiments, the patterned mask layer 61 (see FIG. 11) may be consumed and removed during the first via etching process.

In some embodiments, a bottom 711b of the first hole 711 is at a level that is substantially the same as a level of a bottom 721b of the second hole 721. In some other embodiments not shown herein, the level of the bottom 721b may be slightly higher or lower than the level of the bottom 711b depending on the dimensions of the openings 611, 612 (see FIG. 11). In some embodiments, whether the dimensions of the holes 711, 712 are substantially the same or not, a contour or a shape of the first hole 711 is substantially the same as that of the second hole 721.

After the first via etching process, the filling layer 60 is removed by, for example, but not limited to, an ashing process, a photoresist stripping process, or an etching process.

Referring to FIG. 1 and the example illustrated in FIG. 13, the method 1 proceeds to step S05, where a second via etching process is performed to form a first opening 712 and a second opening 722. The first opening 712 extends downwardly from the first hole 711 and through the first etch stop layer 10. The second opening 722 extends downwardly from the second hole 721 and through the second etch stop layer 20. FIG. 13 is a schematic sectional view similar to that of FIG. 12, but illustrating the structure after step S05 in accordance with some embodiments. After step S05, a first via opening 71 which includes the first hole 711 and the first opening 712, and a second via opening 72 which includes the second hole 721 and the second opening 722 are obtained.

During the second via etching process, the first opening 712 and the second opening 722 are formed simultaneously using the same etchant. In some embodiments, the etchant used in the second via etching process include a halogen-based gas such as a chlorine-based gas, a fluorine-based gas, a bromine-based gas, or a gas mixture thereof. For example, the etchant may include chlorine (Cl₂), hydrogen chloride (HCl), CₓF_{y} (e.g., CF₄, C₄F₈, etc.), nitrogen fluoride (e.g, NF₃, etc.), hydrofluorocarbons (CₓH_{y}F_{z}), hydrogen bromide (HBr), other suitable etchants, or combinations thereof. In some embodiments, the second via etching process may be performed using a plasma etching process. In such case, the etchant (such as the examples described above) is ignited into a plasma remotely and then introduced into a reaction chamber in which the structure shown in FIG. 12 is disposed for the plasma etching process.

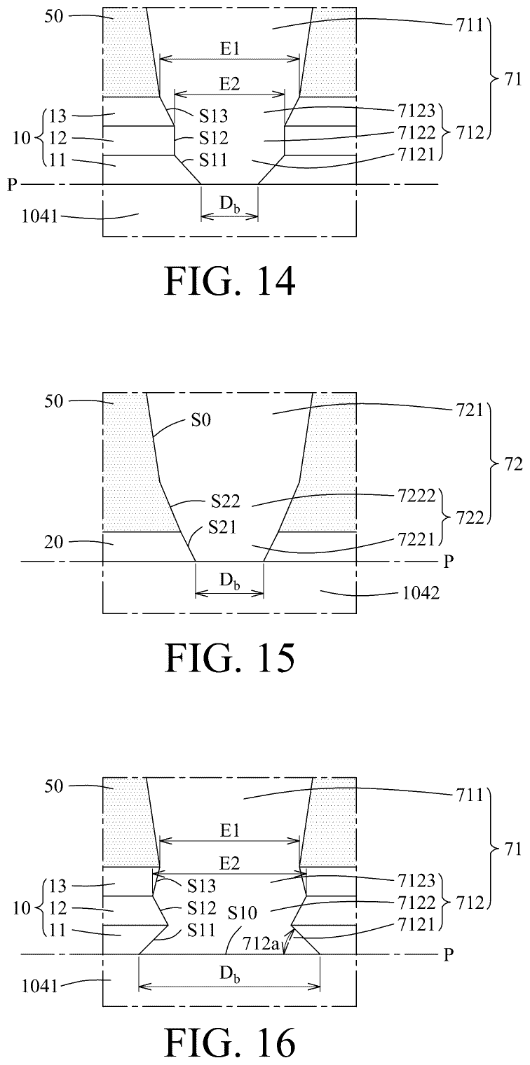

FIG. 14 is an enlarged fragmentary view of area A shown in FIG. 13, and FIG. 15 is an enlarged fragmentary view of area B shown in FIG. 13 in accordance with some embodiments. It is worth noting that a contour or a shape of the first opening 712 is different from that of the second opening 722. The first opening 712 includes an upper part 7123, a middle part 7122 and a lower part 7121 which respectively penetrate t he sub-layers 13, 12, 11 of the first etch stop layer 10. The second opening 722 has an upper part 7222 formed in the dielectric layer 50 and a lower part 7221 penetrating the second etch stop layer 20.

Referring to FIG. 14, an inner surface S11 of the lower part 7121 has a first slope, an inner surface S12 of the middle part 7122 has a second slope, and an inner surface S13 of the upper part 7123 has a third slope. Since the sub-layers 11, 12, 13 are patterned at different etch rates, the first, second and third slopes are different from each other. In other words, the inner surfaces S11, S12, S13 are inclined with respect to an imaginary plane (P) parallel to an upper surface of the dielectric layer 103 (see FIG. 13) by different angles. The second slope of the inner surface S12 (i.e., an infinite slope) is greater than the third slope of the inner surface S13, and the third slope of the inner surface S13 is greater than the first slope of the inner surface S11. In some embodiments, the dielectric constant of the first dielectric material of the sub-layer 11 is greater than the dielectric constant of the third dielectric material of the sub-layer 13, and the dielectric constant of the third dielectric material of the sub-layer 13 is greater than the dielectric constant of the second dielectric material of the sub-layer 12.

To be specific, the sub-layer 11, the sub-layer 12 and the sub-layer 13 are patterned at a first etch rate (ER1), a second etch rate (ER2) and a third etch rate (ER3), respectively. The lower, middle and upper parts 7121, 7122, 7123 each has an upper edge which has a first dimension (E1), and a lower edge which has a second dimension (E2). A dimension change (dE) is obtained by subtracting the first dimension (E1) from the second dimension (E2), that is, dE=E2−E1. For the structure shown in FIG. 14, the second etch rate (ER2) is greater than the third etch rate (ER3), and the third etch rate (ER3) is greater than the first etch rate (ER1). That is, ER2>ER3>ER1. Hence, the dimension change (dE₂) of the middle part 7122 is greater than the dimension change (dE₃) of the upper part 7123, and the dimension change (dE₃) of the upper part 7123 is greater than the dimension change (dE₁) of the lower part 7121. That is, dE₂>dE₃>dE₁ (or dE₂≈0>dE₃>dE₁). It is noted that the dimension change (dE₃, dE₁) of each of the upper and lower parts 7123, 7121 results in a negative value, which indicates that each of the upper and lower parts 7123, 7121 tapers in a direction toward the substrate 101. In the case that the dimension change (dE) results in a negative value, a tapering degree can be calculated by dividing an absolute value of the dimension change (dE) by a depth (D) of the part of the hole, i.e., tapering degree=|dE|/D. A tapering degree of the lower part 7121 is greater that of the upper part 7123. The dimension change (dE₂) of the middle part 7122 is substantially equal to zero, and thus the middle part 7122 does not taper substantially. In some embodiments, a ratio of the second dimension (E2) of the lower edge of the lower part 7021 (i.e., a bottom dimension (D_{b}) of the via opening 71 shown in FIG. 14) to the first dimension (E1) of the upper edge of the upper part 7023 may less than about 1, for example, may range from about 0.3 to about 0.9, or from about 0.3 to about 0.5.

Referring to FIG. 15, an inner surface S21 of the lower part 7221 of the second opening 722 has a slope that is substantially the same as the third slope of the inner surface S13, because the second etch stop layer 20 and the sub-layer 13 of the first etch stop layer 10 are made of the same dielectric material (i.e., the third dielectric material) and thus are patterned at the same etch rate (i.e., the first etch rate). In other words, the inner surfaces S21, S13 are inclined with respect to the imaginary plane (P) by substantially the same angle.

Still referring to FIG. 15, although the second hole 721 and the upper part 7222 of the second opening 722 located immediately beneath the second hole 721 are both formed in the lower portion of the dielectric layer 50, the second hole 721 is formed during the first via etching process, and the upper part 7222 of the second opening 722 is formed during the second via etching process. In the case that the etchant used in the second via etching process is different from an etchant used in the first via etching process, an inner surface S0 of the second hole 721 and an inner surface S22 of the upper part 7222 of the second opening 722 may be inclined with respect to the imaginary plane (P) by different angles. The slope of the inner surface S0 is greater than the slope of the inner surface S22, and the slope of the inner surface S22 is greater than the slope of the inner surface S21.

FIG. 16 is a schematic sectional view similar to that of FIG. 14, but illustrating a variant of the configuration of the first etch stop layer 10, and the configuration of the first opening 712 thus obtained in accordance with some other embodiments.

The first etch stop layer 10 shown in FIG. 16 has a configuration similar to that of the first etch stop layer 10 shown in FIG. 14, but the first etch rate (ER1) of the first sub-layer 11 is greater than the third etch rate (ER3) of the third sub-layer 13, and the third etch rate (ER3) of the third sub-layer 13 is greater than the second etch rate (ER2) of the second sub-layer 12. That is, ER1>ER3>ER2. Accordingly, the dimension change (dE₁) of the lower part 7121 is greater than the dimension change (dE ₃) of the upper part 7123, and the dimension change (dE₃) of the upper part 7123 is greater than the dimension change (dE₂) of the middle part 7122. That is, dE₁>dE₃>dE₂ (or dE₁>dE₃>0>dE₂). The dimension change (dE₃, dE₁) of each of the upper and lower parts 7123, 7121 results in a positive value, which indicates that each of the upper and lower parts 7123, 7121 flares in the direction toward the substrate 101. In the case that the dimension change (dE) results in a positive value, a flaring degree can be calculated by dividing the dimension change (dE) by the depth (D) of the part of the hole, i.e., flaring degree=dE/D. A flaring degree of the lower part 7121 is greater that of the upper part 7123. On the contrary, the middle part 7122 does not flare but tapers in the direction toward the substrate 101. In some embodiments, a ratio of the second dimension (E2) of the lower edge of the lower part 7021 (i.e., a bottom dimension (D_{b}) of the via opening 71 shown in FIG. 16) to the first dimension (E1) of the upper edge of the upper part 7023 may greater than about 1, for example, may range from about 1 to about 1.5. In some embodiments shown in FIG. 16, the dielectric constant of the second dielectric material of the sub-layer 12 is greater than the dielectric constant of the third dielectric material of the sub-layer 13, and the dielectric constant of the third dielectric material of the sub-layer 13 is greater than the dielectric constant of the first dielectric material of the sub-layer 11.

In the lower part 7121 of the first opening 712, a bottom surface S10 and the inner surface S11 form an angle 712a. When the first etch rate (ER1) is greater than the second etch rate (ER2), the angle 712a may be less than about 90 degrees. In some embodiments, the first etch rate (ER1) is not greater than, for example, but not limited to, about ten times the second etch rate (ER2), so as to permit the angle 712a to be not less than about 45 degrees. As such, poor gap filling in the lower part 7121 of the first opening 712 may be alleviated or eliminated.

The bottom dimension (D_{b}) of the via opening 71 shown in FIG. 16 may be larger than the bottom dimension (D_{b}) of the via opening 71 shown in FIG. 14 due to different configurations of the first etch stop layer 10. In certain embodiments, the bottom dimension (D_{b}) of the via opening 71 may be about 1.05 to about 1.5 times the bottom dimension (D_{b}) of the via opening 72, especially when the via openings 71, 72 have the same upper dimension (Dᵤ) (see FIG. 13). In some other embodiments not shown herein, the bottom dimension (D_{b}) of the via opening 71 may be smaller than the bottom dimension (D_{b}) of the via opening 72 after appropriate modification of the dielectric materials of the etch stop layers 10, 20. In certain embodiments, the bottom dimension (D_{b}) of the via opening 71 may be about 0.5 to 0.95 times the bottom dimension (D_{b}) of the via opening 72, especially when the via openings 71, 72 have the same upper dimension (Dᵤ).

The second via etching process is performed using the sub-layers 511, 512 (see FIG. 12) as a hard mask. In some embodiments, the sub-layer 512 may be consumed and removed during the second via etching process, leaving the sub-layer 511 on the dielectric layer 50.

Referring to FIG. 1 and the examples illustrated in FIGS. 13 and 17, the method 1 proceeds to step S06, where a first conductive feature 81 are formed to fill the first trench 501 and the first via opening 71, and a second conductive feature 82 are formed to fill the second trench 502 and the second via opening 72, thereby obtaining the interconnecting layer Mₓ. FIG. 17 is a schematic sectional view similar to that of FIG. 13, but illustrating the structure after step S06 in accordance with some embodiments. The conductive features 81, 82 may be also referred to as upper conductive features.

The conductive features 81, 82 are respectively connected to the conductive features 1041, 1042. In some embodiments, the conductive features 81, 82 each includes a diffusion barrier layer 801 and a conductive portion 802. The diffusion barrier layer 801 is disposed to separate the conductive portion 802 from the dielectric layer 50. Possible materials suitable for forming the diffusion barrier layer 801 and the conductive portion 802 are respectively similar to those for forming the diffusion barrier layer 105 and the conductive portion 106 as described above with reference to FIG. 2, and thus the details thereof are omitted for the sake of brevity. In some embodiments, the conductive features 81, 82 are formed by electrochemical plating, electroless deposition, CVD, PVD, ALD, or other suitable deposition techniques, followed by a planarization process (e.g., chemical mechanical polishing) to expose the dielectric layer 50.

Referring to FIGS. 13 and 17, the conductive feature 81 has a line portion 81a formed in the first trench 501 and a via portion 81b formed in the first via opening 71. The conductive feature 82 has a line portion 82a formed in the second trench 502 and a second via portion 82b formed in the second via opening 72.

It can be observed that a contour or shape of the via portion 81b is complied with that of the first via opening 71, and a contour or shape of the via portion 82b is complied with that of the second via opening 72. Since the contours or shapes of the via openings 71, 72 are different, the contour or shape of the via portion 81b is different from that of the via portion 82b.

Referring to FIGS. 14 and 17, the first via portion 81b has an upper part 811 formed in the first hole 711, and a lower part 812 formed in the first opening 712. The lower part 812 has an upper region, a middle region and a lower region respectively extending through the sub-layers 13, 12, 11 of the first etch stop layer 10. Peripheral surfaces of the upper, middle and lower regions of the lower part 812 are respectively complied with the inner surfaces S13, S12, S11 of the upper, middle and lower parts 7123, 7122, 7121 of the first opening 712, and thus the details thereof are omitted for the sake of brevity.

Referring to FIGS. 15 and 17, the second via portion 82b has an upper part 821 formed in the second hole 721, and a lower part 822 formed in the second opening 722. The lower part 822 has an upper region and a lower region respectively formed in the dielectric layer 50 and the second etch stop layer 20. Peripheral surfaces of the upper and lower regions of the lower part 822 are respectively complied with the inner surfaces S22, S21 of the upper lower parts 7222, 7221 of the second opening 722, and thus the details thereof are omitted for the sake of brevity.

In some embodiments, as shown in FIG. 17, the peripheral surface of the upper region of the lower part 812 of the first via portion 81b has a contour or slope that is substantially the same as the contour or slope of the lower region of the lower part of the second via portion 82b.

FIG. 18 is a schematic sectional view similar to that of FIG. 16, but further illustrating the first via portion 81b formed in the first via opening 71. A contour or shape of the via portion 81b shown in FIG. 18 is complied with that of the first via opening 71 shown in FIG. 16, and thus the details thereof are omitted for the sake of brevity.

In some embodiments, the semiconductor structure 2 may be further formed with an interconnect layer Mₓ₊₁ which is formed over the interconnect layer Mₓ. In some embodiments, the interconnect layer Mₓ₊₁ may have a configuration similar to that of the interconnect layer Mₓ₋₁. In some other embodiments not shown herein, the interconnect layer Mₓ₊₁ may have a configuration similar to that of the interconnect layer Mₓ. The interconnect layer Mₓ₊₁ may be formed by a dual damascene process, a single damascene process, or other suitable back-end-of-line (BEOL) techniques.

It is noted that the interconnect layer Mₓ shown in FIG. 17 is configured as a dual damascene structure which includes metal lines (i.e., the line portions 81a, 82a) and metal vias (i.e., the via portions 81b, 82b). In some other embodiments not shown herein, after appropriate modification, the interconnect layer Mₓ may be configured as a single damascene structure which includes the via portions 81b, 82b formed to penetrate the dielectric layer 50. In such case, the line portions 81a, 82a are formed in another dielectric layer which is formed over the dielectric layer 50 after formation of the via portions 81b, 82b.

FIG. 19 is a schematic sectional view illustrating the semiconductor structure 2 in accordance with some embodiments, in which the interconnect layer Mₓ is applied to an interconnect layer M₀. In such case, the conductive features 104 are respectively connected to the via portions 81b, 82b, and are each a gate electrode of the semiconductor device 102. As shown in FIG. 19, the semiconductor device 102 includes a first transistor 1021 and a second transistor 1022. Each of the first and second transistors 1021, 1022 includes a channel (Ch), two source/drain portions (SD) respectively located at two opposite sides of the channel (Ch), a gate electrode (G1 or G2) disposed on the channel (Ch) and capable of controlling a current in the channel (Ch), a gate dielectric (not shown) disposed to separate the gate electrode (G1 or G2) from the channel (Ch), and two gate spacers (Sp) respectively disposed at two opposite sides of the gate electrode (G1 or G2). The first and second transistors 1021, 1022 are covered by the dielectric layer 103. In some embodiments, a threshold voltage or other device specifications of the first and second transistors 1021, 1022 may be different from each other. Each of the first and second transistors 1021, 1022 may be configured as a fin-type field-effect transistor (FinFET) structure, a gate-all-around field-effect transistor (GAAFET) structure, a complementary field-effect transistor (CFET) structure which includes a lower GAAFET and an upper GAAFET sequentially formed over a substrate, a fork-sheet structure which includes two GAAFETs spaced part from each other through a wall portion which is formed on a trench isolation, or other suitable three-dimensional structures.

As shown in FIG. 19, the conductive features 1041, 1042 respectively serve as the gate electrodes (G1, G2) of the transistors 1021, 1022. The etch stop layers 10, 20 are respectively formed on the gate electrodes (G1, G2), and each may be also referred to as a hard mask portion. The via portions 81b, 82b respectively extends through the etch stop layers 10, 20 to be respectively connected to the gate electrodes (G1, G2).

In some embodiments, the interconnect layer M₀ may further include multiple metal contacts (MD) and via contacts (VD) formed to be connected to the source/drain portions (SD) of the transistors 1021, 1022. In some embodiments, the dielectric layer 50 may be configured as a multi-layer structure which includes sub-layers 501, 502, 503 stacked on each other for forming the metal contacts (MD), the via contacts (VD), the via portions 81b, 82b, and the line portions 81a, 82a therein. The interconnect layer M₀ are formed after formation of the dielectric layer 103 and the transistors 1021, 1022. In some embodiments, formation of the interconnect layer M₀ may include (i) forming the etch stop layers 10, 20 respectively on the gate electrodes (G1, G2) of the transistors 1021, 1022 in a manner similar to the manner as described above in step S01 (each of the etch stop layers 10, 20 may be further patterned to have a reduced width in a direction between the two source/drain portions (SD) of a respective one of the transistors 1021, 1022), (ii) forming the sub-layer 501 on the dielectric layer 103 to cover the etch stop layers 10, 20 by a suitable deposition process and/or a planarization process, (iii) forming the metal contacts (MD) which extends through the sub-layer 501 and the dielectric layer 103 so as to be respectively connected to the source/drain portions (SD) of the transistors 1021, 1022, (iv) forming the sub-layer 502 on the sub-layer 501 to cover the metal contacts (MD) by a suitable deposition process and/or a planarization process, (v) forming the via portions 81b, 82b each of which extends through the sub-layers 501, 502 and a corresponding one of the etch stop layers 10, 20 so as to be respectively connected to the corresponding gate electrode (G1 or G2) in a manner similar to the manner as described above in steps S04 to S06, (vi) forming the via contacts (VD) in the sub-layer 502 so as to be respectively connected to the metal contacts (MD), (vii) forming the sub-layer 503 on the sub-layer 502 to cover the via portions 81b, 82b and the via contacts (VD) by a suitable deposition process and/or a planarization process, and (viii) forming the line portions 81a, 82a in the sub-layer 503. It is noted that, in some alternative embodiments, the via portions 81b, 82b may be formed after formation of the via contacts (VD), and the sub-layer 503 may be formed after formation of the line portions 81a, 82a.

In some embodiments, some steps in the method 1 may be modified, replaced, or eliminated without departure from the spirit and scope of the present disclosure. In some alternative embodiments, the semiconductor structure 2 and the interconnect layer Mₓ may further include additional features, and/or some features present in the semiconductor structure 2 and the interconnect layer Mₓ may be modified, replaced, or eliminated without departure from the spirit and scope of the present disclosure.

In summary, with the provision of different configurations of the etch stop layers 10, 20, even if the layout design (e.g., size of via or contacts on a reticle or a photomask which is used in a photolithography process) is not changed, the configurations of the via openings 71, 72 may be controlled to be different from each other, thereby resulting in the via portions 81b, 82b (respectively formed in the via openings 71, 72) having different resistances. The contact resistance between the via portion 81b and the conductive feature 1041 may be also different from the contact resistance between the via portion 82b and the conductive feature 1042. In some embodiments, the etch stop layer 10 is configured as a multi-layered structure, and the etch stop layer 20 is configured a single layer structure. In such case, a bottom dimension of the via opening 71 thus formed may be adjusted by varying compositions of the etch stop layer 10 (e.g., varying the ratios of elements or materials in each of the sub-layers 11, 12, 13 so that during formation of the via opening 71 in the etch stop layer 10, the etch rate of each of the sub-layers 11, 12, 13 can be individually adjusted). Since the resistance of the via portions 81b, 82b can be changed independently, the interconnect layer Mₓ or M₀) of this disclosure provides flexibility in circuit design.

In accordance with some embodiments of the present disclosure, a method for manufacturing an interconnect structure includes: forming a first etch stop layer and a second etch stop layer respectively on a first lower conductive portion and a second lower conductive portion, a configuration of the first etch stop layer being different from a configuration of the second etch stop layer, the first lower conductive portion being spaced apart from the second lower conductive portion; forming a dielectric layer to cover the first etch stop layer and the second etch stop layer; performing a first etching process to form a first hole and a second hole in the dielectric layer so as to expose at least one of the first etch stop layer and the second etch stop layer; performing a second etching process to form a first opening which extends downwardly from the first hole and through the first etch stop layer, and to form a second opening which extends downwardly from the second hole and through the second etch stop layer; and after the second etching process, forming a first upper conductive portion in the first hole and the first opening, and forming a second upper conductive portion in the second hole and the second opening.

In accordance with some embodiments of the present disclosure, the first etch stop layer is configured as a multi-layered structure, and the second etch stop layer is configured as a single layer structure.

In accordance with some embodiments of the present disclosure, the first etch stop layer includes a first sub-layer which is formed on the first lower conductive portion and which is made of a first dielectric material, and a second sub-layer which is formed on the first sub-layer opposite to the first lower conductive portion, and which is made of a second dielectric material. In the second etching process, the second dielectric material has an etch rate that is different from an etch rate of the first dielectric material.

In accordance with some embodiments of the present disclosure, the second etch stop layer is made of the second dielectric material.

In accordance with some embodiments of the present disclosure, formation of the first etch stop layer and the second etch stop layer includes forming a first film to cover the first lower conductive portion and the second conductive portion, the first film including the first dielectric material, patterning the first film to expose the second lower conductive portion such that the first film is formed into the first sub-layer of the first etch stop layer, and forming a second film which includes a first portion disposed on the first sub-layer and a second portion disposed on the second conductive portion. The first portion serves as the second sub-layer of the first etch stop layer, and the second portion serves as the second etch stop layer.

In accordance with some embodiments of the present disclosure, during the second etching process, the second sub-layer is patterned to form an upper part of the first opening, and the first sub-layer is patterned to form a lower part of the first opening. A slope of an inner surface of the upper part is different from a slope of an inner surface of the lower part.

In accordance with some embodiments of the present disclosure, a slope of an inner surface of the second opening is the same as the slope of the inner surface of the upper part.

In accordance with some embodiments of the present disclosure, during the second etching process, the first opening and the second opening are formed simultaneously using a same etchant.

In accordance with some embodiments of the present disclosure, a method for manufacturing an interconnect structure includes: forming a first etch stop layer on a first lower conductive portion; forming a second etch stop layer on a second lower conductive portion, the first lower conductive portion being spaced apart from the second lower conductive portion; forming a dielectric layer to cover the first etch stop layer and the second etch stop layer; forming a first upper conductive portion that extends through the dielectric layer and the first etch stop layer; and forming a second upper conductive portion that extends through the dielectric layer and the second etch stop layer. A configuration of the first etch stop layer is different from a configuration of the second etch stop layer so that the first upper conductive portion and the second upper conductive portion are formed to have different contours.

In accordance with some embodiments of the present disclosure, the first etch stop layer and the second etch stop layer are made of different materials.

In accordance with some embodiments of the present disclosure, a thickness of the first etch stop layer is greater than a thickness of the second etch stop layer.

In accordance with some embodiments of the present disclosure, the first etch stop layer includes a first sub-layer which is formed on the first lower conductive portion and which is made of a first dielectric material, and a second sub-layer which is formed on the first sub-layer opposite to the first lower conductive portion, and which is made of a second dielectric material that is different from the first dielectric material. The second etch stop layer is made of one of the first dielectric material and the second dielectric material.

In accordance with some embodiments of the present disclosure, the first dielectric material includes silicon oxide, silicon carbide, silicon nitride, silicon oxynitride, silicon carbon nitride, silicon oxycarbon nitride, aluminum oxide, aluminum nitride, or aluminum oxynitride. The second dielectric material includes silicon oxide, silicon carbide, silicon nitride, silicon oxynitride, silicon carbon nitride, silicon oxycarbon nitride, aluminum oxide, aluminum nitride, or aluminum oxynitride.

In accordance with some embodiments of the present disclosure, the first lower conductive portion serves as a first gate electrode which is capable of controlling a current in a first channel disposed beneath the first gate electrode. The second lower conductive portion serves as a second gate electrode which is capable of controlling a current in a second channel disposed beneath the second gate electrode.

In accordance with some embodiments of the present disclosure, the first etch stop layer is configured as a multi-layered structure, and the second etch stop layer is configured as a single layer structure.

In accordance with some embodiments of the present disclosure, an interconnect structure includes: a first lower conductive portion and a second lower conductive portion which are formed in a lower dielectric layer and which are spaced apart from each other; a first etch stop layer and a second etch stop layer respectively formed on the first lower conductive portion and the second lower conductive portion, a configuration of the first etch stop layer being different from a configuration of the second etch stop layer; an upper dielectric layer formed to cover the first etch stop layer and the second etch stop layer; a first upper conductive portion extending through the upper dielectric layer and the first etch stop layer so as to be electrically connected to the first lower conductive portion; and a second upper conductive portion extending through the upper dielectric layer and the second etch stop layer so as to be electrically connected to the second lower conductive portion.

In accordance with some embodiments of the present disclosure, the first etch stop layer is configured as a multi-layered structure, and the second etch stop layer is configured as a single layer structure.

In accordance with some embodiments of the present disclosure, the first etch stop layer includes a first sub-layer which is formed on the first lower conductive portion and which is made of a first dielectric material, and a second sub-layer which is formed on the first sub-layer opposite to the first lower conductive portion, and which is made of a second dielectric material. The second dielectric material is different from the first dielectric material. The second etch stop layer is made of one of the first dielectric material and the second dielectric material.

In accordance with some embodiments of the present disclosure, the first upper conductive portion has an upper part extending through the upper dielectric layer, and a lower part extending through the first etch stop layer. The lower part has an upper region extending through the second sub-layer and a lower region extending through the first sub-layer. A slope of a peripheral surface of the upper region is different from a slope of a peripheral surface of the lower region.

In accordance with some embodiments of the present disclosure, the second upper conductive portion has an upper part extending through the upper dielectric layer, and a lower part extending through the second etch stop layer. The second etch stop layer is made of the second dielectric material, so that a slope of a peripheral surface of the lower part of the second upper conductive portion is the same as the slope of the peripheral surface of the upper region.

In accordance with some embodiments of the present disclosure, a method for manufacturing an interconnect structure includes: forming a first etch stop layer on a first lower conductive portion; forming a second etch stop layer on a second lower conductive portion, the first lower conductive portion being spaced apart from the second lower conductive portion; forming a dielectric layer to cover the first etch stop layer and the second etch stop layer; forming a first upper conductive portion that extends through the dielectric layer and the first etch stop layer; and forming a second upper conductive portion that extends through the dielectric layer and the second etch stop layer. A contour of an upper part of the first upper conductive portion is the same as a contour of an upper part of the second upper conductive portion, and a contour of a lower part of the first upper conductive portion is different from a contour of a lower part of the second upper conductive portion.

In accordance with some embodiments of the present disclosure, the first etch stop layer is configured as a multi-layered structure, and the second etch stop layer is configured as a single layer structure.

In accordance with some embodiments of the present disclosure, the first etch stop layer includes a first sub-layer which is formed on the first lower conductive portion and which is made of a first dielectric material, and a second sub-layer which is formed on the first sub-layer opposite to the first lower conductive portion, and which is made of a second dielectric material that is different from the first dielectric material. The second etch stop layer is made of one of the first dielectric material and the second dielectric material.

In accordance with some embodiments of the present disclosure, the dielectric layer is made of a third dielectric material that is different from the first dielectric material and the second dielectric material.

In accordance with some embodiments of the present disclosure, the lower part of the first upper conductive portion and the lower part of the second upper conductive portion respectively penetrate the first etch stop layer and the second etch stop layer.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming a first etch stop layer and a second etch stop layer respectively on a first lower conductive portion and a second lower conductive portion, a configuration of the first etch stop layer being different from a configuration of the second etch stop layer, the first lower conductive portion being spaced apart from the second lower conductive portion;
forming a dielectric layer to cover the first etch stop layer and the second etch stop layer;
performing a first etching process to form a first hole and a second hole in the dielectric layer so as to expose at least one of the first etch stop layer and the second etch stop layer;
performing a second etching process to form a first opening which extends downwardly from the first hole and through the first etch stop layer, and to form a second opening which extends downwardly from the second hole and through the second etch stop layer; and
after the second etching process, forming a first upper conductive portion in the first hole and the first opening, and forming a second upper conductive portion in the second hole and the second opening.

2. The method as claimed in claim 1, wherein the first etch stop layer is configured as a multi-layered structure, and the second etch stop layer is configured as a single layer structure.

3. The method as claimed in claim 2, wherein
the first etch stop layer includes
a first sub-layer which is formed on the first lower conductive portion and which is made of a first dielectric material, and
a second sub-layer which is formed on the first sub-layer opposite to the first lower conductive portion, and which is made of a second dielectric material, and
in the second etching process, the second dielectric material has an etch rate that is different from an etch rate of the first dielectric material.

4. The method as claimed in claim 3, wherein the second etch stop layer is made of the second dielectric material.

5. The method as claimed in claim 4, wherein formation of the first etch stop layer and the second etch stop layer includes
forming a first film to cover the first lower conductive portion and the second conductive portion, the first film including the first dielectric material,
patterning the first film to expose the second lower conductive portion such that the first film is formed into the first sub-layer of the first etch stop layer, and
forming a second film which includes a first portion disposed on the first sub-layer and a second portion disposed on the second conductive portion, the first portion serving as the second sub-layer of the first etch stop layer, the second portion serving as the second etch stop layer.

6. The method as claimed in claim 4, wherein, during the second etching process, the second sub-layer is patterned to form an upper part of the first opening, and the first sub-layer is patterned to form a lower part of the first opening, a slope of an inner surface of the upper part being different from a slope of an inner surface of the lower part.

7. The method as claimed in claim 6, wherein a slope of an inner surface of the second opening is the same as the slope of the inner surface of the upper part.

8. The method as claimed in claim 1, wherein, during the second etching process, the first opening and the second opening are formed simultaneously using a same etchant.

9. A method for manufacturing an interconnect structure, comprising:
forming a first etch stop layer on a first lower conductive portion;
forming a second etch stop layer on a second lower conductive portion, the first lower conductive portion being spaced apart from the second lower conductive portion;
forming a dielectric layer to cover the first etch stop layer and the second etch stop layer;
forming a first upper conductive portion that extends through the dielectric layer and the first etch stop layer; and
forming a second upper conductive portion that extends through the dielectric layer and the second etch stop layer;
a configuration of the first etch stop layer being different from a configuration of the second etch stop layer so that the first upper conductive portion and the second upper conductive portion are formed to have different contours.

10. The method as claimed in claim 9, wherein the first etch stop layer and the second etch stop layer are made of different materials.

11. The method as claimed in claim 9, wherein a thickness of the first etch stop layer is greater than a thickness of the second etch stop layer.

12. The method as claimed in claim 11, wherein
the first etch stop layer includes
a first sub-layer which is formed on the first lower conductive portion and which is made of a first dielectric material, and
a second sub-layer which is formed on the first sub-layer opposite to the first lower conductive portion, and which is made of a second dielectric material
that is different from the first dielectric material, and
the second etch stop layer is made of one of the first dielectric material and the second dielectric material.

13. The method as claimed in claim 12, wherein
the first dielectric material includes silicon oxide, silicon carbide, silicon nitride, silicon oxynitride, silicon carbon nitride, silicon oxycarbon nitride, aluminum oxide, aluminum nitride, or aluminum oxynitride, and
the second dielectric material includes silicon oxide, silicon carbide, silicon nitride, silicon oxynitride, silicon carbon nitride, silicon oxycarbon nitride, aluminum oxide, aluminum nitride, or aluminum oxynitride.

14. The method as claimed in claim 9, wherein
the first lower conductive portion serves as a first gate electrode which is capable of controlling a current in a first channel disposed beneath the first gate electrode, and
the second lower conductive portion serves as a second gate electrode which is capable of controlling a current in a second channel disposed beneath the second gate electrode.

15. The method as claimed in claim 14, wherein the first etch stop layer is configured as a multi-layered structure, and the second etch stop layer is configured as a single layer structure.

16. An interconnect structure, comprising:
a first lower conductive portion and a second lower conductive portion which are formed in a lower dielectric layer and which are spaced apart from each other;
a first etch stop layer and a second etch stop layer respectively formed on the first lower conductive portion and the second lower conductive portion, a configuration of the first etch stop layer being different from a configuration of the second etch stop layer;
an upper dielectric layer formed to cover the first etch stop layer and the second etch stop layer;
a first upper conductive portion extending through the upper dielectric layer and the first etch stop layer so as to be electrically connected to the first lower conductive portion; and
a second upper conductive portion extending through the upper dielectric layer and the second etch stop layer so as to be electrically connected to the second lower conductive portion.

17. The interconnect structure as claimed in claim 16, wherein the first etch stop layer is configured as a multi-layered structure, and the second etch stop layer is configured as a single layer structure.

18. The interconnect structure as claimed in claim 17, wherein
the first etch stop layer includes
a first sub-layer which is formed on the first lower conductive portion and which is made of a first dielectric material, and
a second sub-layer which is formed on the first sub-layer opposite to the first lower conductive portion, and which is made of a second dielectric material, the second dielectric material being different from the first dielectric material, and
the second etch stop layer is made of one of the first dielectric material and the second dielectric material.

19. The interconnect structure as claimed in claim 18, wherein the first upper conductive portion has an upper part extending through the upper dielectric layer, and a lower part extending through the first etch stop layer, the lower part having an upper region extending through the second sub-layer and a lower region extending through the first sub-layer, a slope of a peripheral surface of the upper region being different from a slope of a peripheral surface of the lower region.

20. The interconnect structure as claimed in claim 19, wherein
the second upper conductive portion has an upper part extending through the upper dielectric layer, and a lower part extending through the second etch stop layer, and
the second etch stop layer is made of the second dielectric material, so that a slope of a peripheral surface of the lower part of the second upper conductive portion is the same as the slope of the peripheral surface of the upper region.
